(19) United States
(12) Patent Application Publication
(10) Pub. No.: US 2024/0194391 A1
(43) Pub. Date: Jun. 13, 2024

(54) INDUCTOR COMPONENT

(71) Applicant: Murata Manufacturing Co., Ltd., Kyoto-fu (JP)

(72) Inventors: Masaki INUI, Nagaokakyo-shi (JP); Hideki KAMO, Nagaokakyo-shi (JP)

(73) Assignee: Murata Manufacturing Co., Ltd., Kyoto-fu (JP)

(21) Appl. No.: 18/525,472

(22) Filed: Nov. 30, 2023

(30) Foreign Application Priority Data
Dec. 12, 2022 (JP) 2022-197920

(51) Int. Cl. H01F 27/28; H01F 17/00; H01F 27/29; H01F 27/32

(52) U.S. Cl. CPC H01F 27/2804; H01F 17/0013; H01F 27/29; H01F 27/323

(57) ABSTRACT

An inductor component includes an element body; a coil provided in the element body and having a spiral shape along an axis; and first and second outer electrodes on or in the element body and electrically connected to the coil. The element body includes first and second end surfaces opposed to each other, first and second side surfaces opposed to each other, a bottom surface connected between the first and second end surfaces and between the first and second side surfaces, and a top surface opposed to the bottom surface. The element body is composed of an insulator. The axis is parallel to the bottom surface and intersects the first side surface and the second side surface. The thickness of each of first through fourth outer coil wiring layers is smaller than the thickness of each of the inner coil wiring layers.

### CROSS-REFERENCE TO RELATED APPLICATION

This application claims benefit of priority to Japanese Patent Application No. 2022-197920, filed Dec. 12, 2022, the entire content of which is incorporated herein by reference.

### BACKGROUND

### Technical Field

The present disclosure relates an inductor component.

### Background Art

Examples of conventional inductor components include one disclosed in Japanese Unexamined Patent Application Publication No. 2021-27251. This inductor component includes an element body and a coil provided in the element body and wound around an axis. The coil includes a plurality of coil wiring layers laminated along the axis.

### SUMMARY

In such a conventional inductor component, the thickness of each of the coil wiring layers is the same. Here, in the case in which the thicknesses of the coil wiring layers are increased to decrease Rdc, electric current sometimes concentrates in some of the coil wiring layers, which can cause a loss and decrease the Q factor of the inductor component.

Accordingly, the present disclosure provides an inductor component having a high Q factor.

An aspect of the present disclosure provides an inductor component including an element body; a coil provided in the element body and having a spiral shape along an axis; and first and second outer electrodes provided on or in the element body and electrically connected to the coil. The element body includes a first end surface and a second end surface opposed to each other, a first side surface and a second side surface opposed to each other, a bottom surface connected between the first end surface and the second end surface and between the first side surface and the second side surface, and a top surface opposed to the bottom surface. The element body is composed of an insulator. The axis is parallel to the bottom surface and intersects the first side surface and the second side surface. The coil includes a first outer coil wiring layer located at an outermost side portion on one side in an axis direction of the axis, a second outer coil wiring layer provided on an inner side of and next to the first outer coil wiring layer, a third outer coil wiring layer located at an outermost side portion on the other side in the axis direction, a fourth outer coil wiring layer provided on an inner side of and next to the third outer coil wiring layer, and one or more inner coil wiring layers located between the second outer coil wiring layer and the fourth outer coil wiring layer. The thickness of each of the first outer coil wiring layer, the second outer coil wiring layer, the third outer coil wiring layer, and the fourth outer coil wiring layer is smaller than the thickness of each of the inner coil wiring layers. The thickness of a coil wiring layer is defined as the value obtained by determining four cross sections including the axis, measuring the maximum value of the dimension of the coil wiring layer in the direction parallel to the axis in each cross section, and calculating the average value of these maximum values. Examples of the four cross sections include the cross section perpendicular to the top surface and the bottom surface and including the axis, the cross section perpendicular to the first end surface and the second end surface and including the axis, the cross section including the line of intersection of the top surface and the first end surface and the line of intersection of the bottom surface and the second end surface and including the axis, and the cross section including the line of intersection of the top surface and the second end surface and the line of intersection of the bottom surface and the first end surface and including the axis.

The above aspect makes it possible to further disperse electric current and reduce the concentration of electric current. As a result, it is possible to further reduce the loss of electric current and improve the Q factor of the inductor component.

The present disclosure provides an inductor component having a high Q factor.

### BRIEF DESCRIPTION OF THE DRAWINGS

FIG. 1 is a perspective view of an inductor component of a first embodiment;

FIG. 2 is a transparent front view of the inductor component in FIG. 1;

FIG. 3 is a cross-sectional view of the inductor component in FIG. 2 taken along line III-III;

FIG. 4A is an exploded view of the inductor component in FIG. 1;

FIG. 4B is an exploded view of the inductor component in FIG. 1;

FIG. 5 is a graph illustrating a simulation of the inductor component of the first embodiment;

FIG. 6 is a cross-sectional view of an inductor component of a second embodiment; and

FIG. 7 is a cross-sectional view of an inductor component of a third embodiment.

### DETAILED DESCRIPTION

Hereinafter, an inductor component according to an aspect of the present disclosure will be described in detail with reference to implementation configurations illustrated in the figures. Note that some of the drawings are schematic and do not reflect actual dimensions and ratios.

### First Embodiment

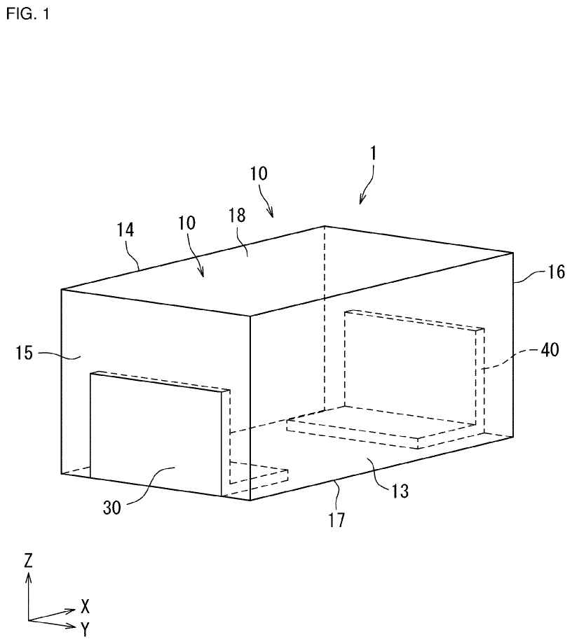

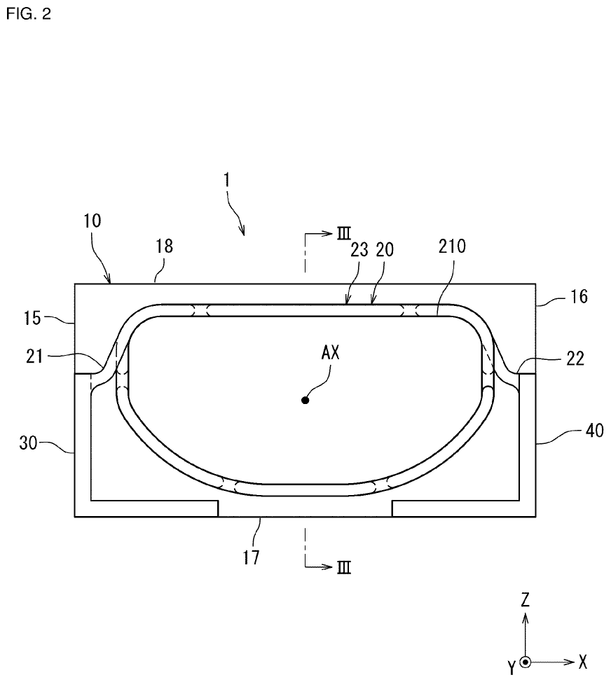

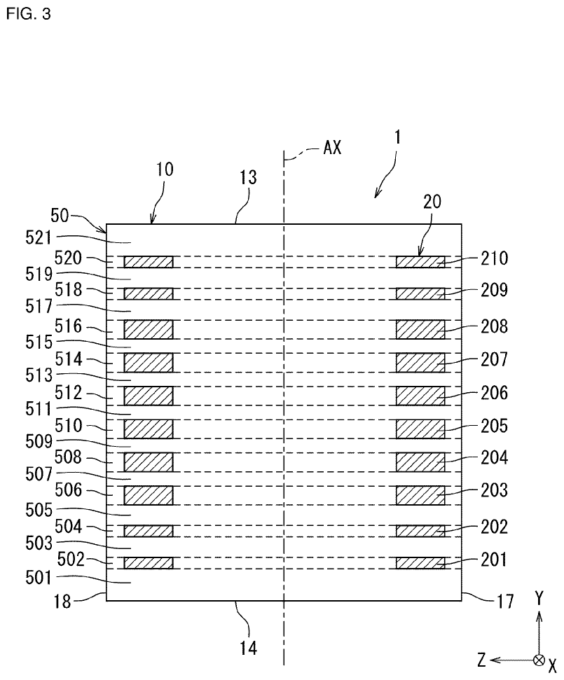

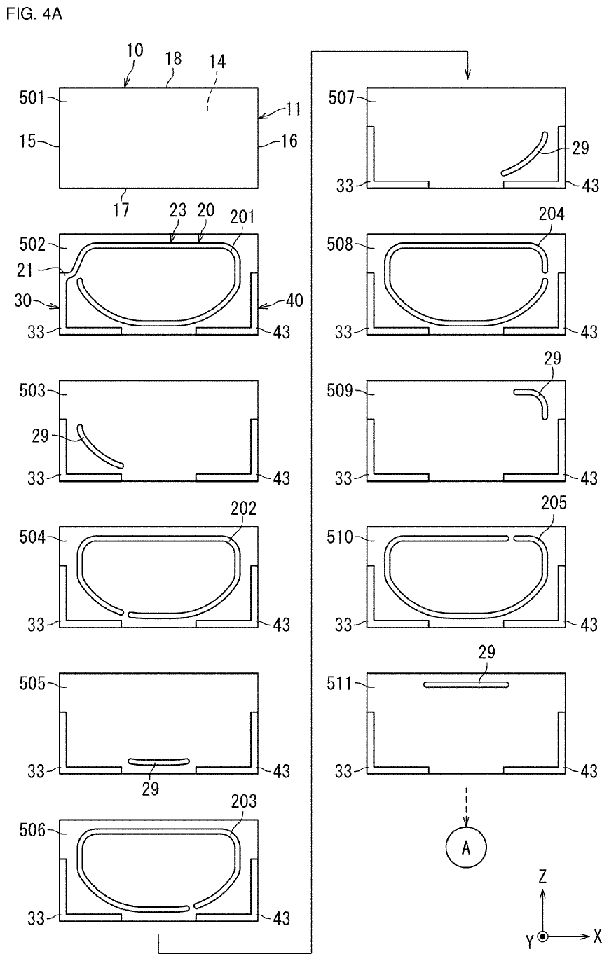

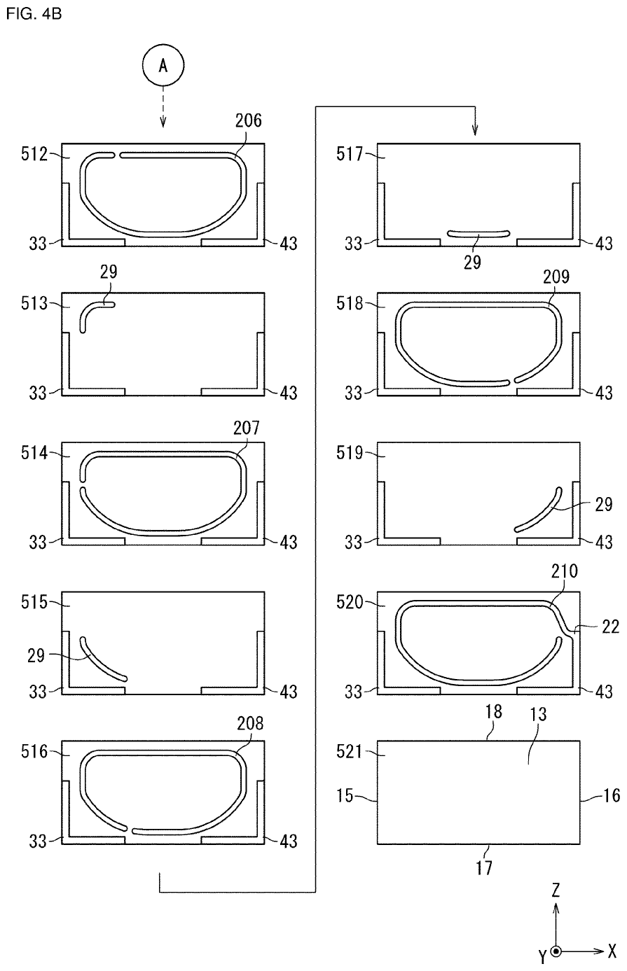

FIG. 1 is a perspective view of an inductor component according to a first embodiment. FIG. 2 is a transparent front view of the inductor component in FIG. 1. FIG. 3 is a cross-sectional view taken along line III-III in FIG. 2. FIGS. 4A and 4B are exploded views of the inductor component in FIG. 1. Note that although FIG. 2 is illustrated as a transparent view for convenience so that the structure can be easily understood, the view may be considered semitransparent or opaque.

As illustrated in FIGS. 1 to 3, the inductor component 1 includes first and second outer electrodes 30 and 40 and is configured to be electrically connected to wiring of a circuit board (not illustrated) with the first and second outer electrodes 30 and 40 interposed therebetween. The inductor component 1 is used, for example, for an impedance matching coil for high-frequency circuits and is hence used for electronic devices such as personal computers (PCs), DVD players, digital cameras, TV sets, mobile phones, car electronics, and medical or industrial machinery. The applications of the inductor component 1 are not limited to these, and, for example, the inductor component 1 can be used for a tuning circuit, a filter circuit, a rectifying and smoothing circuit, and the like.

The element body 10 is formed to be an approximately rectangular parallelepiped. The surfaces of the element body 10 include a first end surface 15 and a second end surface 16 opposed to each other, a first side surface 13 and a second side surface 14 opposed to each other, a bottom surface 17 connected between the first end surface 15 and the second end surface 16 and between the first side surface 13 and the second side surface 14, and a top surface 18 opposed to the bottom surface 17. The bottom surface 17, when the inductor component 1 is mounted on a mounting board (not illustrated), faces the mounting board.

As illustrated in the figures, the X direction is the direction perpendicular to the first end surface 15 and the second end surface 16 and pointing from the first end surface 15 toward the second end surface 16. The Y direction is the direction perpendicular to the first side surface 13 and the second side surface 14 and pointing from the second side surface 14 toward the first side surface 13. The Z direction is the direction perpendicular to the bottom surface 17 and the top surface 18 and pointing from the bottom surface 17 toward the top surface 18. The X direction is also referred to as the length direction of the element body 10, the Y direction as the width direction of the element body 10, and the Z direction as the height direction of the element body 10. The X, Y, and Z directions are orthogonal to one another and constitute a left-handed system when arranged in the order of X, Y, and Z.

The first outer electrode 30 and the second outer electrode 40 are composed of a conductive material, such as Ag, Cu, Au, or an alloy containing any of these as a main component. The first outer electrode 30 and the second outer electrode 40 may have an abovementioned conductive material (for example, Ag, Cu, or Au) as a primary layer and have a Ni plating layer and a Sn plating layer on the primary layer in this order. In this case, the Ni plating layer and the Sn plating layer may rise from the surfaces of the element body 10 so as to cover the primary layer. The first outer electrode 30 is L-shaped and extends over the first end surface 15 and the bottom surface 17. The first outer electrode 30 is embedded in the element body 10 so as to be exposed from the first end surface 15 and the bottom surface 17. The second outer electrode 40 is L-shaped and extends over the second end surface 16 and the bottom surface 17. The second outer electrode 40 is embedded in the element body 10 so as to be exposed from the second end surface 16 and the bottom surface 17. Note that although the first outer electrode 30 and the second outer electrode 40 are L-shaped in the first embodiment, they may have other shapes, for example, a shape exposed only from the bottom surface.

The first outer electrode 30 and the second outer electrode 40 have a configuration in which a plurality of first and second outer electrode conductor layers 33 and 43 embedded in the element body 10 are laminated. Each outer electrode conductor layer 33 extends along the first end surface 15 and the bottom surface 17, and each second outer electrode conductor layer 43 extends along the second end surface 16 and the bottom surface 17. Since this configuration enables the first and second outer electrodes 30 and 40 to be embedded in the element body 10, it is possible to make the inductor component smaller than in a configuration in which separate outer electrodes are added onto the element body 10. In addition, a coil 20 and the first and second outer electrodes 30 and 40 can be formed in the same process, which reduces the variation in the positional relationship between the coil 20 and the first and second outer electrodes 30 and 40 and in turn reduces the variation in the electrical characteristics of the inductor component 1.

The coil 20 is composed of, for example, a conductive material the same as or similar to that of the first and second outer electrodes 30 and 40. A first end of the coil 20 is connected to the first outer electrode 30, and a second end of the coil 20 is connected to the second outer electrode 40. Note that although the coil 20 and the first and second outer electrodes 30 and 40 are formed integrally, and no clear boundary exists between them in the present embodiment, the present disclosure is not limited to this configuration. A configuration in which a coil and outer electrodes are formed of different kinds of material or formed by different methods, and boundaries exist between them, is possible.

The axis AX of the coil 20 is parallel to the bottom surface 17 and intersects the first side surface 13 and the second side surface 14. The coil 20 is wound around the axis AX. The axis AX of the coil 20 corresponds to the Y direction. The axis AX of the coil 20 denotes the center axis of the spiral shape of the coil 20.

The coil 20 includes a wound portion 23, a first extended portion 21 connected between a first end of the wound portion 23 and the first outer electrode 30, and a second extended portion 22 connected between a second end of the wound portion 23 and the second outer electrode 40. Note that although the wound portion 23 and the first and second extended portions 21 and 22 are formed integrally, and no clear boundary exists between them in the present embodiment, the present disclosure is not limited to this configuration. A configuration in which a wound portion and extended portions are formed of different kinds of material or formed by different methods, and boundaries exist between them, is possible.

The wound portion 23 is wound into a spiral shape along the axis AX. In other words, the wound portion 23 denotes a portion in which the coil 20 is wound into a spiral shape so as to overlap itself as viewed in the direction parallel to the axis AX direction. The first and second extended portions 21 and 22 denote portions veering from the overlapped portion. Although the wound portion 23 is approximately rectangular as viewed in the axis AX direction, the present disclosure is not limited to this shape. The shape of the wound portion 23 may be, for example, circular, elliptical, or another shape, such as polygonal.

The element body 10 is composed of an insulator 50, and the insulator 50 includes a plurality of laminated insulating layers. Specifically, the element body 10 includes first to twenty-first insulating layers 501 to 521 laminated in this order in the direction from the second side surface 14 toward the first side surface 13. The first to twenty-first insulating layers 501 to 521 are composed of, for example, a material containing a borosilicate glass as a main component or a material such as a ferrite or a resin. The laminating direction of the first to twenty-first insulating layers 501 to 521 is the direction (the Y direction) parallel to the first and second end surfaces 15 and 16 and the bottom surface 17 of the element body 10 and thus corresponds to the axis AX of the coil 20. In other words, the first to twenty-first insulating layers 501 to 521 extend in the XZ plane. The concept “parallel” in the present application is not limited to a strict parallel relationship and also includes substantially parallel relationships in consideration of a range of realistic variations. Note that in the element body 10, the interfaces between the first to twenty-first insulating layers 501 to 521 are not clear in some cases due to firing or the like.

The first insulating layer 501 (hereinafter also referred to as the first outermost insulating layer 501) has the second side surface 14 which is the surface opposed to the second insulating layer 502. The twenty-first insulating layer 521 (hereinafter also referred to as the second outermost insulating layer 521) has the first side surface 13 which is the surface opposed to the twentieth insulating layer 520. Note that hereinafter the third insulating layer 503 is also referred to as the first outer insulating layer 503, the fifth insulating layer 505 as the second outer insulating layer 505, the seventeenth insulating layer 517 as the fourth outer insulating layer 517, and the nineteenth insulating layer 519 as the third outer insulating layer 519. The seventh insulating layer 507 is also referred to as the first inner insulating layer 507, the ninth insulating layer 509 as the second inner insulating layer 509, the eleventh insulating layer 511 as the third inner insulating layer 511, the thirteenth insulating layer 513 as the fourth inner insulating layer 513, and the fifteenth insulating layer 515 as the fifth inner insulating layer 515.

As illustrated in FIGS. 3, 4A, and 4B, the coil 20 includes a plurality of coil wiring layers 201 to 210 laminated along the axis AX and via wiring layers 29 each extending along the axis AX and connecting coil wiring layers next to one another in the axis AX direction. Note that in FIGS. 4A and 4B, the direction from top left to bottom right corresponds to the laminating direction (the Y direction).

The plurality of coil wiring layers 201 to 210 each pass through an insulating layer in the thickness direction (the Y direction). The coil wiring layers next to each other in the laminating direction are electrically connected to one another in series with each via wiring layer 29 interposed therebetween. As described above, the plurality of coil wiring layers 201 to 210 are electrically connected to one another in series and form a spiral shape. Note that in the above implementation configuration, the via wiring layers 29 each have an arch shape or a straight-line shape as illustrated in FIGS. 4A and 4B but may have another shape, such as circular.

Specifically, the first to tenth coil wiring layers 201 to 210 are laminated in this order in the axis AX direction (the Y direction). An end portion of the first coil wiring layer 201 is electrically connected to a first outer electrode conductor layer 33 of the first outer electrode 30. An end portion of the tenth coil wiring layer 210 is electrically connected to a second outer electrode conductor layer 43 of the second outer electrode 40.

The first outer electrode conductor layer 33 is provided in the second to twentieth insulating layers 502 to 520 so as to extend over the first end surface 15 and the bottom surface 17. The second outer electrode conductor layer 43 is provided in the second to twentieth insulating layers 502 to 520 so as to extend over the second end surface 16 and the bottom surface 17.

The first coil wiring layer 201 is located at an outermost side portion on one side in the axis AX direction (specifically, the second side surface 14 side) and is hereinafter also referred to as the first outer coil wiring layer 201. The second coil wiring layer 202 is located on the inner side of and next to the first outer coil wiring layer 201 in the axis AX direction and is hereinafter also referred to as the second outer coil wiring layer 202. The tenth coil wiring layer 210 is located at an outermost side portion on the other side in the axis AX direction (specifically, the first side surface 13 side) and is hereinafter also referred to as the third outer coil wiring layer 210. The ninth coil wiring layer 209 is provided on the inner side of and next to the third outer coil wiring layer 210 in the axis AX direction and is hereinafter also referred to as the fourth outer coil wiring layer 209. The third coil wiring layer 203, the fourth coil wiring layer 204, the fifth coil wiring layer 205, the sixth coil wiring layer 206, the seventh coil wiring layer 207, and the eighth coil wiring layer 208 are located between the second outer coil wiring layer 202 and the fourth outer coil wiring layer 209 and are hereinafter also referred to as the first inner coil wiring layer 203, the second inner coil wiring layer 204, the third inner coil wiring layer 205, the fourth inner coil wiring layer 206, the fifth inner coil wiring layer 207, and the sixth inner coil wiring layer 208, respectively.

The first to tenth coil wiring layers 201 to 210 are each wound along a plane. Although the number of turns of each of the first to tenth coil wiring layers 201 to 210 is less than one, it may be one or more. In addition, although the six layers, the first to sixth inner coil wiring layers 203 to 208, are illustrated in the above implementation configuration, the number of inner coil wiring layers is not particularly limited and has only to be one or more.

The first outermost insulating layer 501 has the second side surface 14 of the element body 10 and is in contact with the second insulating layer 502 on the surface opposite to the second side surface 14. The first outer coil wiring layer 201 is provided on or in the second insulating layer 502 (the XZ plane) perpendicular to the axis AX direction and is connected to a first outer electrode conductor layer 33 with the first extended portion 21 interposed therebetween. The first outer insulating layer 503 has a via wiring layer 29, which is connected to the first outer coil wiring layer 201. The second outer coil wiring layer 202 is provided on or in the fourth insulating layer 504 perpendicular to the axis AX direction and is connected to the via wiring layer 29 of the first outer insulating layer 503. The second outer insulating layer 505 has a via wiring layer 29, which is connected to the second outer coil wiring layer 202. The first inner coil wiring layer 203 is provided on or in the sixth insulating layer 506 perpendicular to the axis AX direction and is connected to the via wiring layer 29 of the second outer insulating layer 505. The first inner insulating layer 507 has a via wiring layer 29, which is connected to the first inner coil wiring layer 203. The second inner coil wiring layer 204 is provided on or in the eighth insulating layer 508 perpendicular the axis AX direction and is connected to the via wiring layer 29 of the first inner insulating layer 507. The second inner insulating layer 509 has a via wiring layer 29, which is connected to the second inner coil wiring layer 204. The third inner coil wiring layer 205 is provided on or in the tenth insulating layer 510 perpendicular to the axis AX direction and is connected to the via wiring layer 29 of the second inner insulating layer 509. The third inner insulating layer 511 has a via wiring layer 29, which is connected to the third inner coil wiring layer 205. The fourth inner coil wiring layer 206 is provided on or in the twelfth insulating layer 512 perpendicular to the axis AX direction and is connected to the via wiring layer 29 of the third inner insulating layer 511. The fourth inner insulating layer 513 has a via wiring layer 29, which is connected to the fourth inner coil wiring layer 206. The fifth inner coil wiring layer 207 is provided on or in the fourteenth insulating layer 514 perpendicular to the axis AX direction and is connected to the via wiring layer 29 of the fourth inner insulating layer 513. The fifth inner insulating layer 515 has a via wiring layer 29, which is connected to the fifth inner coil wiring layer 207. The sixth inner coil wiring layer 208 is provided on or in the sixteenth insulating layer 516 perpendicular to the axis AX direction and is connected to the via wiring layer 29 of the fifth inner insulating layer 515. The fourth outer insulating layer 517 has a via wiring layer 29, which is connected to the sixth inner coil wiring layer 208. The fourth outer coil wiring layer 209 is provided on or in the eighteenth insulating layer 518 perpendicular to the axis AX direction and is connected to the via wiring layer 29 of the fourth outer insulating layer 517. The third outer insulating layer 519 has a via wiring layer 29, which is connected to the fourth outer coil wiring layer 209. The third outer coil wiring layer 210 is provided on or in the twentieth insulating layer 520 perpendicular to the axis AX direction, is connected to the via wiring layer 29 of the third outer insulating layer 519, and is connected to a second outer electrode conductor layer 43 with the second extended portion 22 interposed therebetween. The second outermost insulating layer 521 is in contact with the twentieth insulating layer 520 and has the first side surface 13 of the element body 10 on the surface opposite to the twentieth insulating layer 520.

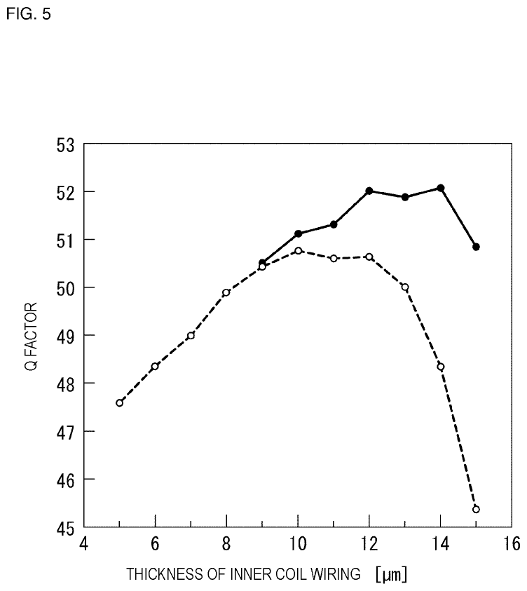

Here, the inventors of the present application performed a verification with a thin first outer coil wiring layer 201 and a thin third outer coil wiring layer 210 and found that even if the first and third outer coil wiring layers 201 and 210 are thin, it is impossible to make the Q factor sufficiently large. In contrast, it was found that in a case in which the first to fourth outer coil wiring layers 201, 202, 210, and 209 are thin, the Q factor is large, as illustrated in FIG. 5 and the like. Specifically, the thickness of each of the first outer coil wiring layer 201, the second outer coil wiring layer 202, the third outer coil wiring layer 210, and the fourth outer coil wiring layer 209 is smaller than the thickness of each of the first to sixth inner coil wiring layers 203 to 208.

Here, the thickness of a coil wiring layer is defined as the value obtained by determining four cross sections including the axis AX, measuring the maximum value of the dimension of the coil wiring layer in the direction parallel to the axis AX in each cross section, and calculating the average value of these maximum values. Examples of the four cross sections include the cross section perpendicular to the top surface 18 and the bottom surface 17 and including the axis AX, the cross section perpendicular to the first end surface 15 and the second end surface 16 and including the axis AX, the cross section including the line of intersection of the top surface 18 and the first end surface 15 and the line of intersection of the bottom surface 17 and the second end surface 16 and including the axis AX, and the cross section including the line of intersection of the top surface 18 and the second end surface 16 and the line of intersection of the bottom surface 17 and the first end surface 15 and including the axis AX.

The relationship between the thickness of the inner coil wiring layers and the Q factor of the inductor component 1 will be described with reference to FIG. 5. In FIG. 5, the X-axis represents the thickness (μm) of each inner coil wiring layer, and the Y-axis represents the Q factor at 2 GHz. Specifically, in FIG. 5, the solid line indicates the relationship between the thickness of each of the first to sixth inner coil wiring layers 203 to 208 and the Q factor at each thickness. In this verification, the average value of the thicknesses of the first to fourth outer coil wiring layers 201, 202, 210, and 209 is smaller than the average value of the thicknesses of the first to sixth inner coil wiring layers 203 to 208. The thicknesses of the first to fourth outer coil wiring layers 201, 202, 210, and 209 are the same, and the thicknesses of the first to sixth inner coil wiring layers 203 to 208 are the same. The thicknesses of the first to fourth outer coil wiring layers 201, 202, 210, and 209 are fixed to 8 μm, and the thicknesses of the first to sixth inner coil wiring layers 203 to 208 are varied in a range of 9 to 15 μm. In FIG. 5, the dotted line indicates the Q factor of a comparative example in which the thicknesses of the coil wiring layers are the same. FIG. 5 indicates that in the case in which the thicknesses of the first to fourth outer coil wiring layers 201, 202, 210, and 209 are small (the solid line), the Q factor is higher than in the case in which the thicknesses are the same (the dotted line).

Note that the measurement illustrated in FIG. 5 is the results of the measurement simulation of the Q factor conducted by using an electromagnetic field simulator HFSS (3D electromagnetic field simulator for RF/wireless design). In the simulation, the frequency is 2 GHz, the dimensions of the element body 10 are 4 mm×2 mm×2 mm, the width of the line of the coil wiring layer is 10 μm, the number of turns of the coil is 8.5, the number of coil wiring layers is 10, and the thickness of the coil length is 175 μm.

Note that the coil length denotes the thickness of the element body 10 excluding the first outermost insulating layer 501 and the second outermost insulating layer 521 as viewed in a direction perpendicular to the axis AX direction, in other words, the thickness from the surface of the second insulating layer 502 on the first outermost insulating layer 501 side to the surface of the twentieth insulating layer 520 on the second outermost insulating layer 521 side. The thicknesses of the first to fifth inner insulating layers 507, 509, 511, 513, and 515 are uniform and have values obtained by (175 μm−thickness of the first to sixth inner coil wiring layers 203 to 208×10)/9. The thicknesses of the first to fourth outer insulating layers 503, 505, 519, and 517 are uniform and have values obtained by (175 μm−thickness of the first to sixth inner coil wiring layers 203 to 208×6−thickness of the first to fifth inner insulating layers 507, 509, 511, 513, and 515×5−thickness of the first to fourth outer coil wiring layers 201, 202, 210, and 209×4)/4. The thickness of the insulating layer of the coil wiring layer in the comparative example has a value obtained by (175 μm−thickness of the coil wiring layer×10)/9.

The thickness of each of the first outer coil wiring layer 201, the second outer coil wiring layer 202, the third outer coil wiring layer 210, and the fourth outer coil wiring layer 209 is smaller than the thickness of each of the first to sixth inner coil wiring layers 203 to 208. With the configuration described above, the cross-sectional areas of the first to fourth outer coil wiring layers 201, 202, 210, and 209 are small. This configuration disperses electric current and reduces the concentration of electric current. As a result, it is possible to reduce the loss of electric current and improve the Q factor of the inductor component. Note that although the thicknesses of the first outer coil wiring layer 201, the second outer coil wiring layer 202, the third outer coil wiring layer 210, and the fourth outer coil wiring layer 209 are the same in the present embodiment, they may differ from one another. In addition, although the thicknesses of the first to sixth inner coil wiring layers 203 to 208 are the same, they may differ from one another.

It is preferable that the thickness of each of the first outer insulating layer 503 between the first outer coil wiring layer 201 and the second outer coil wiring layer 202, the second outer insulating layer 505 between the second outer coil wiring layer 202 and the first inner coil wiring layer 203, the third outer insulating layer 519 between the third outer coil wiring layer 210 and the fourth outer coil wiring layer 209, and the fourth outer insulating layer 517 between the fourth outer coil wiring layer 209 and the sixth inner coil wiring layer 208 be larger than the thickness of each of the first to fifth inner insulating layers 507, 509, 511, 513, and 515 between the first to sixth inner coil wiring layers 203 to 208 next to one another in the axis AX direction. The configuration mentioned above makes it possible to disperse electric current and reduce the concentration of electric current. As a result, it is possible to reduce the loss of electric current and improve the Q factor of the inductor component. Note that although the thicknesses of the first outer insulating layer 503, the second outer insulating layer 505, the third outer insulating layer 519, and the fourth outer insulating layer 517 are the same in the present embodiment, they may differ from one another. In addition, although the thicknesses of the first to fifth inner insulating layers 507, 509, 511, 513, and 515 are the same, they may differ from one another.

Note that the thickness of an insulating layer is defined as the value obtained by determining four cross sections including the axis AX, measuring the minimum value of the distance between the coil wiring layers in the direction parallel to the axis AX in each cross section, and calculating the average value of these minimum values. Examples of the four cross sections include the cross section perpendicular to the top surface 18 and the bottom surface 17 and including the axis AX, the cross section perpendicular to the first end surface 15 and the second end surface 16 and including the axis AX, the cross section including the line of intersection of the top surface 18 and the first end surface 15 and the line of intersection of the bottom surface 17 and the second end surface 16 and including the axis AX, and the cross section including the line of intersection of the top surface 18 and the second end surface 16 and the line of intersection of the bottom surface 17 and the first end surface 15 and including the axis AX.

It is preferable that the average value of the thicknesses of the first to sixth inner coil wiring layers 203 to 208 be within a range of 120% to 175% of the average value of the thicknesses of the first outer coil wiring layer 201, the second outer coil wiring layer 202, the third outer coil wiring layer 210, and the fourth outer coil wiring layer 209. The above configuration makes it possible to reliably disperse electric current and reduce the concentration of electric current. As a result, it is possible to reduce the loss of electric current and further improve the Q factor of the inductor component.

### Method of Manufacturing Inductor Component 1

As illustrated from top to bottom in FIG. 4A, the first outer coil wiring layer 201 is provided on the first outermost insulating layer 501, and a plurality of the via wiring layers 29 and the second outer coil wiring layer 202, the first inner coil wiring layer 203, the second inner coil wiring layer 204, and the third inner coil wiring layer 205 are then alternately laminated. Next, as illustrated from top to bottom in FIG. 4B, the fourth inner coil wiring layer 206, the fifth inner coil wiring layer 207, the sixth inner coil wiring layer 208, the fourth outer coil wiring layer 209, and the third outer coil wiring layer 210 and a plurality of the via wiring layers 29 are alternately provided, and the second outermost insulating layer 521 is then further laminated on the third outer coil wiring layer 210. The via wiring layers 29 are provided so as to connect the first and second outer coil wiring layers 201 and 202, the first to sixth inner coil wiring layers 203 to 208, and the fourth and third outer coil wiring layers 209 and 210 to one another. The inductor component 1 is manufactured through these processes.

The first and second outer coil wiring layers 201 and 202, the first to sixth inner coil wiring layers 203 to 208, and the fourth and third outer coil wiring layers 209 and 210 are provided on or in the insulating layers by, for example, screen printing. The via wiring layers 29 are each provided by forming a cavity in an insulating layer by, for example, a photolithography method or a laser method and then performing printing in the cavity of the insulating layer by, for example, screen printing.

### Second Embodiment

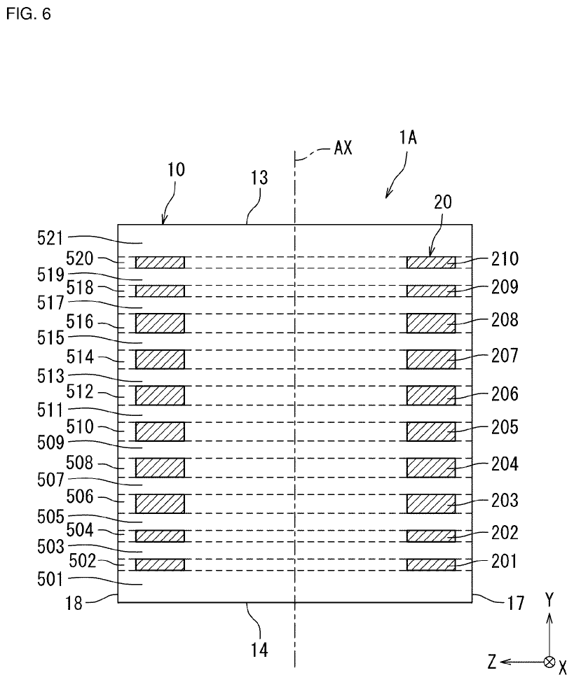

FIG. 6 is a cross-sectional view of an inductor component 1A. A second embodiment differs from the first embodiment in the thickness of the insulating layers. This different portion will be described below. The other portions are the same as those in the first embodiment, and description thereof is omitted.

The thickness of the first outer insulating layer 503 between the first outer coil wiring layer 201 and the second outer coil wiring layer 202, the thickness of the second outer insulating layer 505 between the second outer coil wiring layer 202 and the first inner coil wiring layer 203, and the thickness of the third outer insulating layer 519 between the third outer coil wiring layer 210 and the fourth outer coil wiring layer 209, the thickness of the fourth outer insulating layer 517 between the fourth outer coil wiring layer 209 and the sixth inner coil wiring layer 208, and the thicknesses of the first to fifth inner insulating layers 507, 509, 511, 513, and 515 between the first to sixth inner coil wiring layers 203 to 208 next to one another in the axis direction are the same. The configuration mentioned above makes it possible to further disperse electric current and reduce the concentration of electric current. As a result, it is possible to further reduce the loss of electric current and further improve the Q factor of the inductor component. In addition, it is easy to provide the insulating layers.

### Third Embodiment

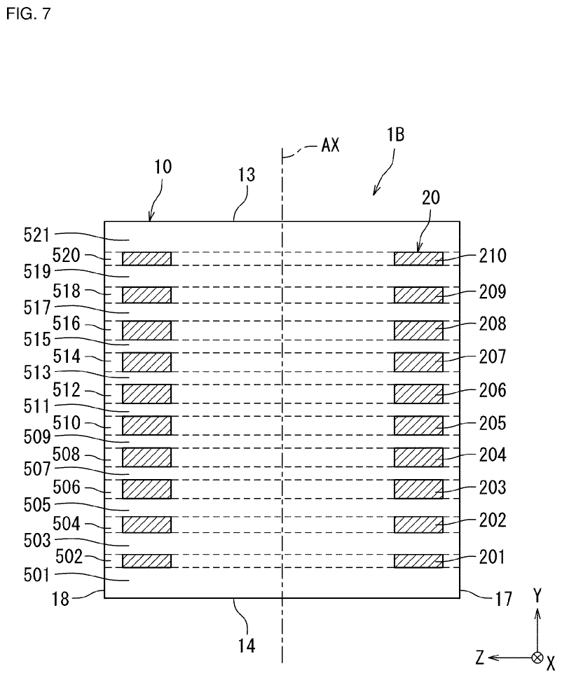

FIG. 7 is a cross-sectional view of an inductor component 1B. A third embodiment will be described with reference to the cross-sectional view of the inductor component 1B. The third embodiment differs from the first embodiment in the thickness of the insulating layers. This different portion will be described below. The other portions are the same as those in the first embodiment, and description thereof is omitted.

The thickness of the first outer coil wiring layer 201 is smaller than the second outer coil wiring layer 202. This configuration makes it possible to reliably disperse electric current and reduce the concentration of electric current. As a result, it is possible to further reduce the loss of electric current and improve the Q factor of the inductor component.

It is preferable that thickness of the third outer coil wiring layer 210 be smaller than thickness of the fourth outer coil wiring layer 209. This configuration makes it possible to reliably disperse electric current and reduce the concentration of electric current. As a result, it is possible to further reduce the loss of electric current and further improve the Q factor of the inductor component. Note that the thicknesses of the first outer coil wiring layer 201 and the third outer coil wiring layer 210 may differ from each other. The thicknesses of the second outer coil wiring layer 202 and the fourth outer coil wiring layer 209 may also differ from each other. In addition, the thicknesses of the first to sixth inner coil wiring layers 203 to 208 may differ from one another.

Note that the present disclosure is not limited to the embodiments described above, and the design may be changed within a scope not departing from the spirit of the present disclosure. For example, the features of the first to third embodiments may be combined in various ways.

The present disclosure includes the following configurations.

<1> An inductor component including an element body; a coil provided in the element body and having a spiral shape along an axis; and first and second outer electrodes provided on or in the element body and electrically connected to the coil. The element body includes a first end surface and a second end surface opposed to each other, a first side surface and a second side surface opposed to each other, a bottom surface connected between the first end surface and the second end surface and between the first side surface and the second side surface, and a top surface opposed to the bottom surface. The element body is composed of an insulator. The axis is parallel to the bottom surface and intersects the first side surface and the second side surface. The coil includes a first outer coil wiring layer located at an outermost side portion on one side in an axis direction of the axis, a second outer coil wiring layer provided on an inner side of and next to the first outer coil wiring layer, a third outer coil wiring layer located at an outermost side portion on an other side in the axis direction, a fourth outer coil wiring layer provided on an inner side of and next to the third outer coil wiring layer, and one or more inner coil wiring layers located between the second outer coil wiring layer and the fourth outer coil wiring layer. A thickness of each of the first outer coil wiring layer, the second outer coil wiring layer, the third outer coil wiring layer, and the fourth outer coil wiring layer is smaller than a thickness of each of the inner coil wiring layers.

<2> The inductor component according to <1>, in which the insulator includes a plurality of laminated insulating layers. A thickness of each of an insulating layer included in the laminated insulating layers and located between the first outer coil wiring layer and the second outer coil wiring layer, an insulating layer included in the laminated insulating layers and located between the second outer coil wiring layer and the inner coil wiring layers, an insulating layer included in the laminated insulating layers and located between the third outer coil wiring layer and the fourth outer coil wiring layer, and an insulating layer included in the laminated insulating layers and located between the fourth outer coil wiring layer and the inner coil wiring layers is larger than a thickness of an insulating layer included in the laminated insulating layers and located between the inner coil wiring layers next to one another in the axis direction.

<3> The inductor component according to <1>, in which the insulator includes a plurality of laminated insulating layers. A thickness of an insulating layer included in the laminated insulating layers and located between the first outer coil wiring layer and the second outer coil wiring layer, a thickness of an insulating layer included in the laminated insulating layers and located between the second outer coil wiring layer and the inner coil wiring layers, a thickness of an insulating layer included in the laminated insulating layers and located between the third outer coil wiring layer and the fourth outer coil wiring layer, a thickness of an insulating layer included in the laminated insulating layers and located between the fourth outer coil wiring layer and the inner coil wiring layers, and a thickness of an insulating layer included in the laminated insulating layers and located between the inner coil wiring layers next to one another in the axis direction are same.

<4> The inductor component according to any one of <1> to <3>, in which thicknesses of the inner coil wiring layers are within a range of 120% to 175% of an average value of thicknesses of the first outer coil wiring layer, the second outer coil wiring layer, the third outer coil wiring layer, and the fourth outer coil wiring layer.

<5> The inductor component according to any one of <1> to <4>, in which the thickness of the first outer coil wiring layer is smaller than the thickness of the second outer coil wiring layer.

<6> The inductor component according to any one of <1> to <5>, in which the thickness of the third outer coil wiring layer is smaller than the thickness of the fourth outer coil wiring layer.

What is claimed is:

1. An inductor component comprising:
an element body;
a coil in the element body and having a spiral shape along an axis; and
first and second outer electrodes on or in the element body and electrically connected to the coil, wherein
the element body includes a first end surface and a second end surface opposed to each other, a first side surface and a second side surface opposed to each other, a bottom surface connected between the first end surface and the second end surface and between the first side surface and the second side surface, and a top surface opposed to the bottom surface,
the element body includes an insulator,
the axis is parallel to the bottom surface and intersects the first side surface and the second side surface,
the coil includes a first outer coil wiring layer at an outermost side portion on one side in an axis direction of the axis, a second outer coil wiring layer on an inner side of and next to the first outer coil wiring layer, a third outer coil wiring layer at an outermost side portion on an other side in the axis direction, a fourth outer coil wiring layer on an inner side of and next to the third outer coil wiring layer, and one or more inner coil wiring layers between the second outer coil wiring layer and the fourth outer coil wiring layer, and
a thickness of each of the first outer coil wiring layer, the second outer coil wiring layer, the third outer coil wiring layer, and the fourth outer coil wiring layer is smaller than a thickness of each of the inner coil wiring layers.

2. The inductor component according to claim 1, wherein
the insulator includes a plurality of laminated insulating layers, and
a thickness of each of an insulating layer included in the laminated insulating layers and between the first outer coil wiring layer and the second outer coil wiring layer, an insulating layer included in the laminated insulating layers and between the second outer coil wiring layer and the inner coil wiring layers, an insulating layer included in the laminated insulating layers and between the third outer coil wiring layer and the fourth outer coil wiring layer, and an insulating layer included in the laminated insulating layers and between the fourth outer coil wiring layer and the inner coil wiring layers is larger than a thickness of an insulating layer included in the laminated insulating layers and between the inner coil wiring layers next to one another in the axis direction.

3. The inductor component according to claim 1, wherein
the insulator includes a plurality of laminated insulating layers, and
a thickness of an insulating layer included in the laminated insulating layers and between the first outer coil wiring layer and the second outer coil wiring layer, a thickness of an insulating layer included in the laminated insulating layers and between the second outer coil wiring layer and the inner coil wiring layers, a thickness of an insulating layer included in the laminated insulating layers and between the third outer coil wiring layer and the fourth outer coil wiring layer, a thickness of an insulating layer included in the laminated insulating layers and between the fourth outer coil wiring layer and the inner coil wiring layers, and a thickness of an insulating layer included in the laminated insulating layers and between the inner coil wiring layers next to one another in the axis direction are same.

4. The inductor component according to claim 1, wherein
thicknesses of the inner coil wiring layers are within a range of 120% to 175% of an average value of thicknesses of the first outer coil wiring layer, the second outer coil wiring layer, the third outer coil wiring layer, and the fourth outer coil wiring layer.

5. The inductor component according to claim 1, wherein
the thickness of the first outer coil wiring layer is smaller than the thickness of the second outer coil wiring layer.

6. The inductor component according to claim 1, wherein
the thickness of the third outer coil wiring layer is smaller than the thickness of the fourth outer coil wiring layer.

7. The inductor component according to claim 4, wherein
the thickness of the first outer coil wiring layer is smaller than the thickness of the second outer coil wiring layer.

8. The inductor component according to claim 4, wherein
the thickness of the third outer coil wiring layer is smaller than the thickness of the fourth outer coil wiring layer.
